(19) United States
(12) Patent Application Publication
(10) Pub. No.: US 2025/0104970 A1
(43) Pub. Date: Mar. 27, 2025

(54) ELECTRICAL VARIABLE CAPACITOR CIRCUIT AND SEMICONDUCTOR PROCESSING SYSTEM COMRPISING SAME

(71) Applicant: INDUSTRIAL COOPERATION FOUNDATION JEONBUK NATIONAL UNIVERSITY, Jeonju-si, Jeollabuk-do (KR)

(72) Inventors: Yongsug SUH, Jeonju-si (KR); Juhwa MIN, Jeonju-si (KR)

(73) Assignee: INDUSTRIAL COOPERATION FOUNDATION JEONBUK NATIONAL UNIVERSITY, Jeonju-si, Jeollabuk-do (KR)

(21) Appl. No.: 18/725,767

(22) PCT Filed: Aug. 17, 2022
(86) PCT No.: PCT/KR2022/012271

§ 371 Date: Jun. 29, 2024

(30) Foreign Application Priority Data
Dec. 29, 2021 (KR) 10-2021-0190504

(51) Int. Cl. H01J 37/32

(52) U.S. Cl. CPC H01J 37/32183; H01J 37/32174; H01J 2237/334

(57) ABSTRACT

According to the present invention, disclosed is an electrical variable capacitor circuit and a semiconductor processing system comprising same. The semiconductor processing system of the present invention comprises: an RF power supply, which generates and supplies RF power; a plasma chamber, which receives the RF power from the RF power supply; and an impedance matching circuit, which is arranged between the RF power supply and the plasma chamber so as to match output impedance to the plasma chamber, wherein the impedance matching circuit includes a plurality of electrical variable capacitor circuits, and at least one of the plurality of electrical variable capacitor circuits includes: a first node connected to one side of the RF power supply; a second node connected to the other side of the RF power supply; a variable capacitor connected to the first node; an inductor connected in parallel to the variable capacitor; a switch connected in series to the inductor; and a PIN diode connected in parallel to the inductor and the switch.

### TECHNICAL FIELD

The present invention relates to an impedance matching circuit, and more specifically, to an electrical variable capacitor applied to an impedance matching circuit and a semiconductor processing system including the same.

### BACKGROUND ART

Recently, interest in semiconductor manufacturing processes is increasing every year. In particular, among semiconductor manufacturing processes, a radio frequency (RF) plasma process may be a representative etching process. The etching process using an RF plasma system includes an RF power supply, a plasma load, and an impedance matching circuit.

The impedance matching circuit matches the impedance between a load and an input to ensure maximum power transmission to a plasma chamber at all times. The plasma load is a load that changes depending on the type and amount of a gas used in the chamber and whether plasma is generated, and the impedance matching circuit is essential to satisfy maximum power transmission. In this case, a capacitor, whose capacitance is mechanically varied and which is referred to as a vacuum variable capacitor, is used in the impedance matching circuit to match impedance in response to a variable load. However, since the vacuum variable capacitor mechanically changes capacitance, an electrical variable capacitor that changes capacitance electrically has been studied due to a slow variation time that accounts for 30% of the etching process.

However, the electrical variable capacitor does not reach the level of satisfying requirements (e.g. reliability, volume, efficiency, weight, number of capacitance values, and the like) to replace the existing vacuum variable capacitor.

Therefore, research on an electrical variable capacitor that can satisfy the above requirements is needed.

### DETAILED DESCRIPTION OF INVENTION

### Technical Problem

The present invention is directed to providing an electrical variable capacitor circuit of which costs and volume are reduced by reducing the number of elements, and a semiconductor processing system including the same.

The present invention is also directed to providing an electrical variable capacitor circuit in which the number of active elements is reduced to simplify the configuration of an external circuit and the voltage stress applied to a switch is reduced to facilitate the application of a high-voltage system, and a semiconductor processing system including the same.

### Technical Solution

One aspect of the present invention provides a semiconductor processing system including a radio frequency (RF) power supply configured to generate and supply RF power, a plasma chamber configured to receive the RF power from the RF power supply, and an impedance matching circuit disposed between the RF power supply and the plasma chamber and configured to match output impedance to the plasma chamber, wherein the impedance matching circuit includes a plurality of electrical variable capacitor circuits, and at least one electrical variable capacitor circuit among the plurality of electrical variable capacitor circuits includes a first node connected to one side of the RF power supply, a second node connected to the other side of the RF power supply, a variable capacitor connected to the first node, an inductor connected to the variable capacitor in parallel, a switch connected to the inductor in series, and a PIN diode connected to the inductor and the switch in parallel.

The plurality of electrical variable capacitor circuits may have the same structure.

The plurality of electrical variable capacitor circuits may include 8 to 28 electrical variable capacitor circuits.

A cathode of the PIN diode may be connected to the variable capacitor, and an anode of the PIN diode may be connected to the second node.

Another aspect of the present invention provides an electrical variable capacitor circuit including a first node connected to one side of a radio frequency (RF) power supply, a second node connected to the other side of the RF power supply, a variable capacitor having one side connected to the first node, a PIN diode having one side and an inductor having one side connected to the other side of the variable capacitor in parallel, and a switch connected to the other side of the inductor in series and connected to the PIN diode in parallel.

A cathode terminal of the PIN diode may be connected to the other side of the variable capacitor, and an anode terminal of the PIN diode may be connected to the second node.

### Advantageous Effects

In accordance with an electrical variable capacitor circuit and a semiconductor processing system including the same of the present invention, the volume of a circuit can be reduced by reducing the number of elements, and price competitiveness can be achieved using relatively inexpensive physical elements.

In addition, the configuration of an external circuit can be simplified by reducing the number of active elements, the reliability of a switch can be increased by minimizing the voltage and current stress applied to a switch, and the application of a high voltage system can be facilitated.

### BRIEF DESCRIPTION OF DRAWINGS

FIG. 1 is a diagram for describing a semiconductor processing system according to an embodiment of the present invention.

FIG. 2 is a diagram for describing an impedance matching circuit including a plurality of electrical variable capacitor circuits according to the embodiment of the present invention.

FIG. 3A is a diagram for describing the structure of a first type electrical variable capacitor circuit according to an embodiment of the present invention in detail.

FIG. 3B is a diagram for describing the structure of a second type electrical variable capacitor circuit according to another embodiment of the present invention in detail.

FIG. 4A is a diagram for describing an impedance matching circuit including a plurality of electrical variable capacitor circuits according to another embodiment of the present invention.

FIG. 4B is a diagram for describing the structure of a third type electrical variable capacitor circuit shown in FIG. 4A in detail.

FIGS. 5 to 8 are diagrams for describing a conventional electrical variable capacitor circuit.

FIG. 9 is a diagram for describing simulation waveforms and experimental waveforms of the electrical variable capacitor circuit according to the embodiment of the present invention.

FIG. 10 is a diagram for describing a capacitance variation time of the electrical variable capacitor circuit according to the embodiment of the present invention.

FIG. 11 is a diagram for describing the voltage stress at a switch in the electrical variable capacitor circuit according to the embodiment of the present invention.

FIG. 12A is a diagram illustrating a current variation in the first type electrical variable capacitor circuit according to the embodiment of the present invention.

FIG. 12B is a diagram illustrating a current variation in the third type electrical variable capacitor circuit according to the embodiment of the present invention.

FIG. 13A is a diagram illustrating an inductor current variation in a conventional variable capacitor circuit.

FIG. 13B is a diagram illustrating an inductor current variation in the third type electrical variable capacitor circuit according to the embodiment of the present invention.

### MODES OF THE INVENTION

Hereinafter, embodiments of the present invention will be described in detail with reference to the accompanying drawings. First, in giving reference numerals to components of the drawings, the same reference numerals are given to the same components as much as possible even if the same components are shown in different drawings. In addition, in the following description of the present invention, if a detailed description of related known configurations or functions is obvious to those skilled in the art or is determined to obscure the gist of the present invention, the detailed description thereof will be omitted.

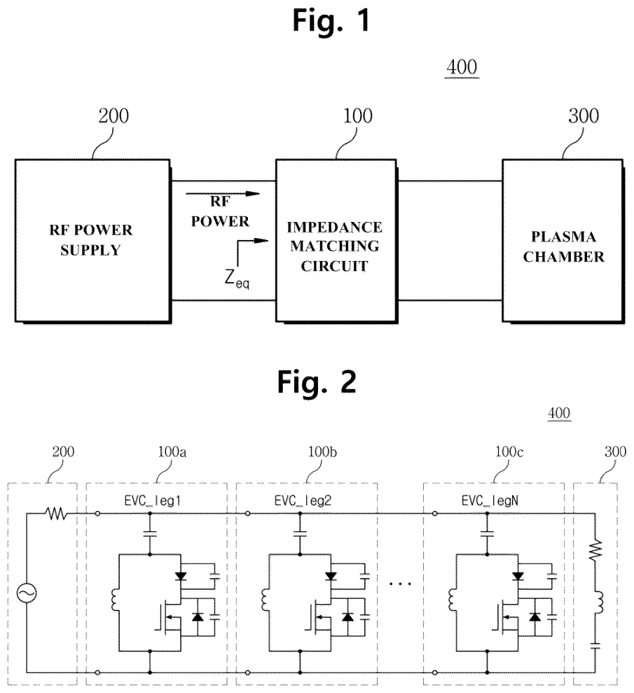

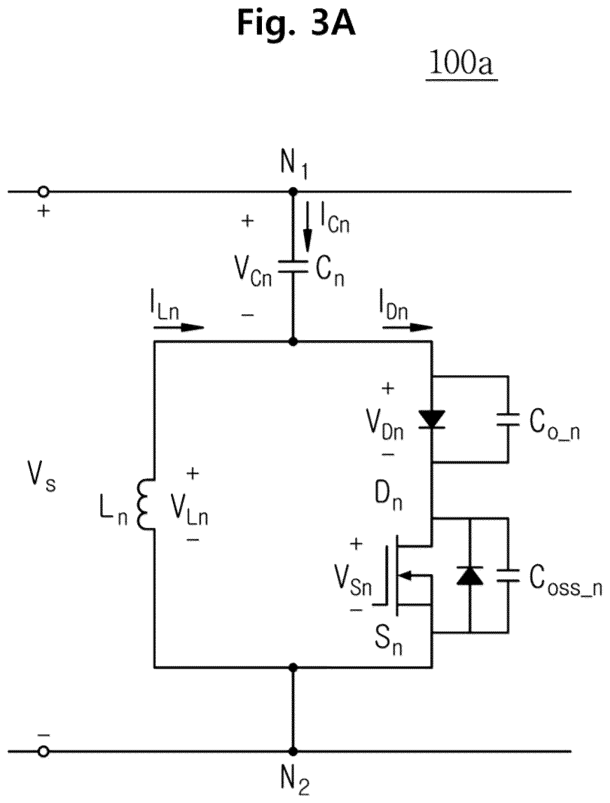

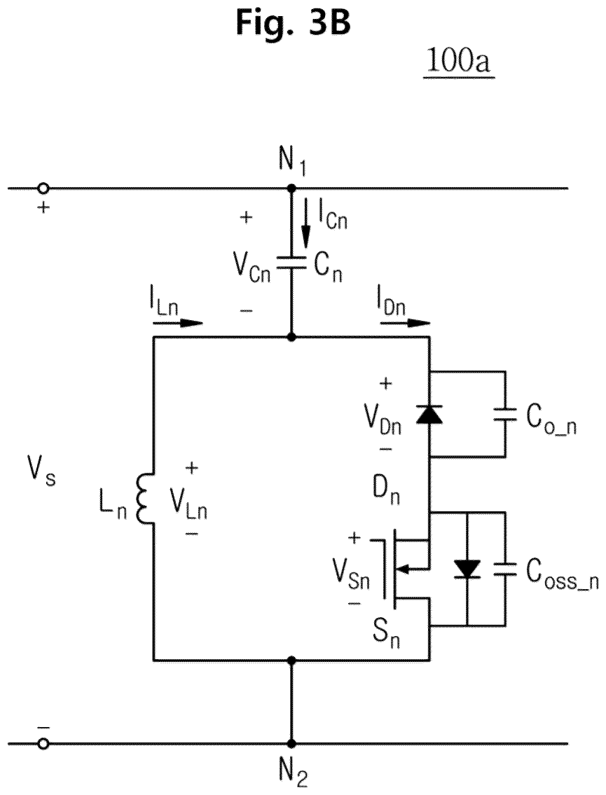

FIG. 1 is a diagram for describing a semiconductor processing system according to an embodiment of the present invention, FIG. 2 is a diagram for describing an impedance matching circuit including a plurality of electrical variable capacitor circuits according to the embodiment of the present invention, FIG. 3A is a diagram for describing the structure of a first type electrical variable capacitor circuit according to an embodiment of the present invention in detail, and FIG. 3B is a diagram for describing the structure of a second type electrical variable capacitor circuit according to another embodiment of the present invention in detail.

Referring to FIGS. 1 to 3B, a semiconductor processing system 400 includes an impedance matching circuit 100 including electrical variable capacitor circuits 100a, 100b, and 100c, a radio frequency (RF) power supply 200, and a plasma chamber 300 which is a load.

The RF power supply 200 generates and supplies RF power, and the plasma chamber 300 receives the RF power from the RF power supply 200. The impedance matching circuit is disposed between the RF power supply 200 and the plasma chamber 300 to match output impedance to the plasma chamber 300. For example, when the RF power in the RF power supply 200 is fixed to a system impedance of 50 ohms of the impedance matching circuit 100, the impedance matching circuit 100 may operate for impedance matching with the plasma chamber 300.

Specifically, the impedance matching circuit 100 may include a plurality of electrical variable capacitor circuits 100a, 100b, and 100c, and the electrical variable capacitor circuits 100a, 100b, and 100c may be divided into leg cells EVC_leg1, EVC_leg2, . . . , and EVC_legN. The plurality of electrical variable capacitor circuits may have the same structure and may include 8 to 28 leg cells, but the present invention is not limited thereto.

The electrical variable capacitor circuit 100a corresponding to a first leg cell EVC_leg1 among the plurality of electrical variable capacitor circuits 100a, 100b, and 100c may include a variable capacitor Cₙ connected to the RF power supply 200 in parallel, a PIN diode Dₙ connected to the variable capacitor Cₙ in parallel, a switch Sₙ (e.g., metal oxide semiconductor field effect transistor (MOSFET)) connected to the PIN diode Dₙ in series, and an inductor Lₙ connected to the variable capacitor Cₙ and switch Sₙ in parallel. The switch Sₙ may be disposed to maintain the connection of the PIN diode Dₙ or disconnect the PIN diode Dₙ in response to processor control. The semiconductor processing system 400 may further include a gate driver for controlling the switch Sₙ and a processor for controlling the gate driver.

Each of the first type electrical variable capacitor circuits 100a, 100b, and 100c (hereinafter, description will be made based on 100a) in FIG. 3A includes the variable capacitor Cₙ, the PIN diode Dₙ, the switch Sₙ, and the inductor Lₙ, which are disposed between a first node N1 connected to a first terminal of the RF power supply 200 and a second node N2 connected to a second terminal thereof. The variable capacitor Cₙ receives an input current I_{Cn} transmitted through the first node N1. The PIN diode Dₙ is connected to the variable capacitor Cₙ in parallel and receives the input current I_{Cn} through an anode. The switch Sₙ is connected to a cathode of the PIN diode Dₙ in series. The inductor Lₙ is connected to the variable capacitor Cₙ and the switch Sₙ in parallel.

A second type electrical variable capacitor circuit 100a in FIG. 3B includes a variable capacitor Cₙ, a PIN diode Dₙ, a switch Sₙ, and an inductor Lₙ, which are disposed between the first node N1 connected to the first terminal of the RF power supply 200 and the second node N2 connected to the second terminal thereof. The variable capacitor Cₙ receives an input current I_{Cn} transmitted through the first node N1. The PIN diode Dₙ is connected to the variable capacitor Cₙ in parallel and receives the input current I_{Cn} through a cathode. The switch Sₙ is connected to an anode of the PIN diode Dₙ in series. The inductor Lₙ is connected to the variable capacitor Cₙ and the switch Sₙ in parallel.

In the first and second type electrical variable capacitor circuits 100a having the above-described structures, when positive (+) power of AC power is supplied from the RF power supply 200, the input current I_{Cn} may be supplied through the first node N1 and, when negative (−) power of the AC power is supplied, the inductor current I_{Ln} may flow in the inductor Lₙ and a switch current Iₛₙ may flow in the switch Sₙ.

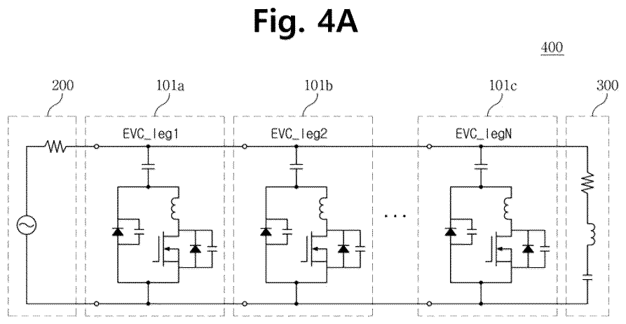

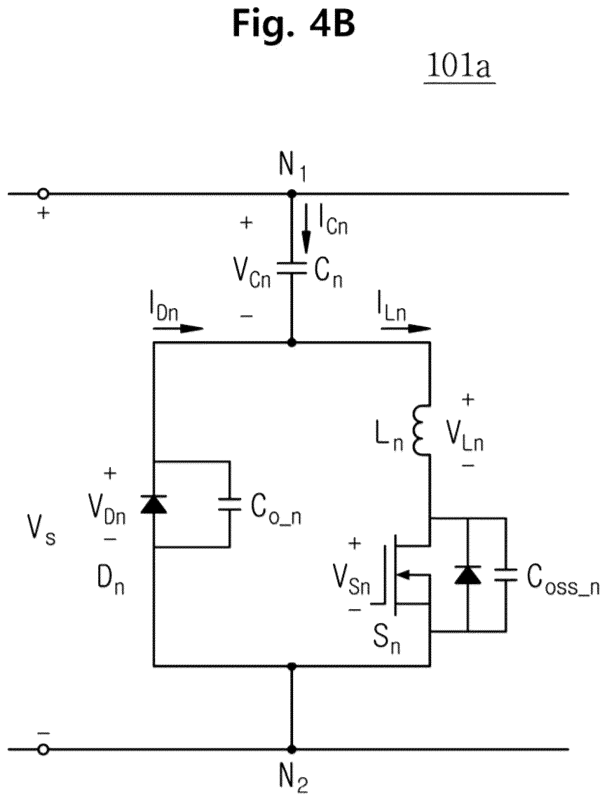

FIG. 4A is a diagram for describing an impedance matching circuit including a plurality of electrical variable capacitor circuits according to another embodiment of the present invention, and FIG. 4B is a diagram for describing the structure of a third type electrical variable capacitor circuit according to an embodiment of the present invention in detail. The semiconductor processing system to which the third type electrical variable capacitor circuit of the present invention described below is applied may reduce the voltage stress applied to the switch to facilitate the application of a high voltage system and may improve reliability against a low voltage and current stress of the switch.

Referring to FIGS. 4A and 4B, a semiconductor processing system 400 according to another embodiment of the present invention includes an impedance matching circuit 101 including third type electrical variable capacitor circuits 101a, 101b, and 101c, an RF power supply 200, and a plasma chamber 300 which is a load.

The RF power supply 200 may include the same configuration as the RF power supply 200 previously described in FIGS. 1 and 2. For example, the RF power supply 200 may generate and supply RF power to the plasma chamber 300 through the impedance matching circuit 101. The plasma chamber 300 has the same configuration as the plasma chamber 300 previously described in FIGS. 1 and 2 and receives the RF power from the RF power supply 200 through the impedance matching circuit 101.

The impedance matching circuit 101 is disposed between the RF power supply 200 and the plasma chamber 300 to match output impedance to the plasma chamber 300. For example, when the RF power in the RF power supply 200 is fixed to a system impedance of 50 ohms of the impedance matching circuit 100, the impedance matching circuit 100 may operate for impedance matching with the plasma chamber 300.

Specifically, the impedance matching circuit 100 may include a plurality of third type electrical variable capacitor circuits 101a, 101b, and 101c, and the third type electrical variable capacitor circuits 101a, 101b, and 101c may be divided into leg cells EVC_leg1, EVC_leg2, . . . , and EVC_legN. The plurality of third type electrical variable capacitor circuits 101a, 101b, and 101c may have the same structure and include 8 to 28 leg cells similar to the first and second type electrical variable capacitor circuits 100a, 100b, and 100c, but the present invention is not limited thereto.

The third type electrical variable capacitor circuit 101a corresponding to a first leg cell EVC_leg1 among the plurality of third type electrical variable capacitor circuits 101a, 101b, and 101c may include a variable capacitor Cₙ connected to the RF power supply 200 in parallel, a PIN diode Dₙ connected to the variable capacitor Cₙ in parallel, an inductor Lₙ connected to the PIN diode Dₙ in parallel, and a switch Sₙ connected to the inductor Lₙ in series and connected to the PIN diode Dₙ in parallel. The switch Sₙ may be disposed to maintain the connection of the inductor Lₙ or disconnect the inductor Lₙ in response to processor control. One end of the variable capacitor Cₙ is connected to the first node N1 of the RF power supply 200, and the other end of the variable capacitor Cₙ is connected between a cathode terminal of the PIN diode Dₙ and one end of the inductor Iₙ. An anode terminal of the PIN diode Dₙ is connected to the second node N2, and one end of the switch Sₙ is connected to the second node N2. The other end of the switch Sₙ is connected to the other end of the inductor Iₙ. According to another aspect, the third type electrical variable capacitor circuit 101a may include a variable capacitor Cₙ disposed between the first node N1 connected to one side of the RF power supply 200 and the second node N2 connected to the other side thereof, an inductor In connected to the variable capacitor Cₙ in parallel, a switch Sₙ connected to the inductor Iₙ in series, and a PIN diode Dₙ connected to the inductor In and the switch Sₙ in parallel.

An operating state of the third type electrical variable capacitor circuit 101a with the above-described structure may be changed by the configuration of the gate driver and the processor included in the semiconductor processing system 400. When the switch Sₙ is turned on by processor control, AC power of the RF power supply 200 may be supplied to the variable capacitor Cₙ, a low DC current may flow in the switch Sₙ in the turned-on state, and DC+AC power may flow in the PIN diode Dₙ.

Meanwhile, in the above description, although the plurality of electrical variable capacitor circuits included in the impedance matching circuits 100 and 101 have been described as including one of the first to third type electrical variable capacitor circuits, the present invention is not limited thereto. For example, a plurality of electrical variable capacitor circuits in which the first to third types are applied in combination may be applied to the impedance matching circuit. For example, among the electrical variable capacitor circuits included in a specific impedance matching circuit, a first electrical variable capacitor circuit may include the first type electrical variable capacitor circuit, a second electrical variable capacitor circuit may include the second type electrical variable capacitor circuit, and a third electrical variable capacitor circuit may include the third type electrical variable capacitor circuit. Alternatively, at least some of the plurality of electrical variable capacitor circuits may include any one or two or more of the first to third type electrical variable capacitor circuits.

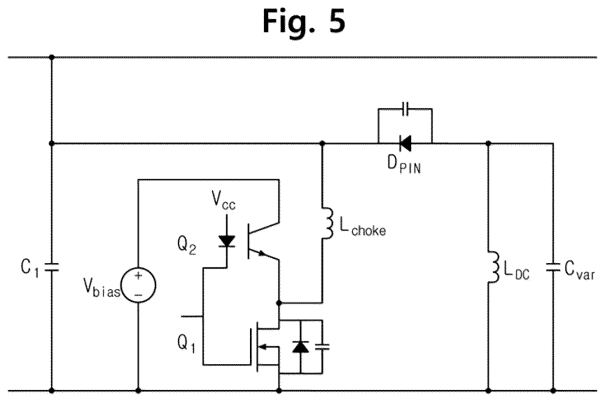

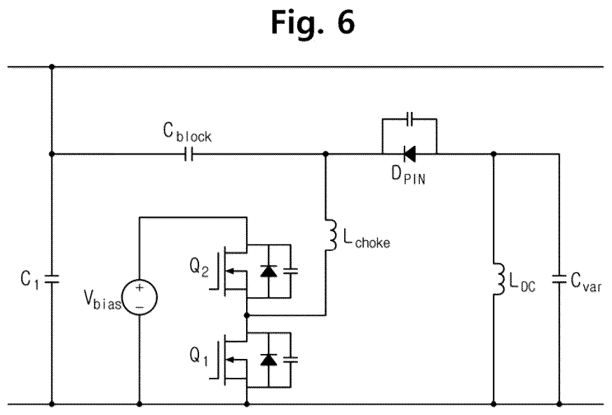

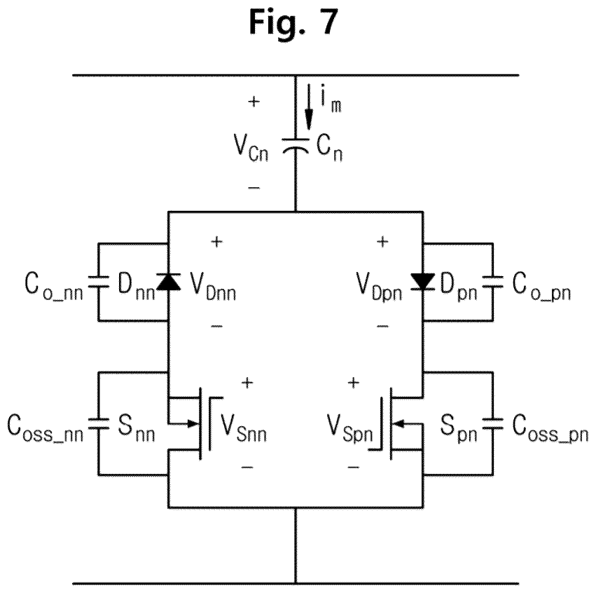

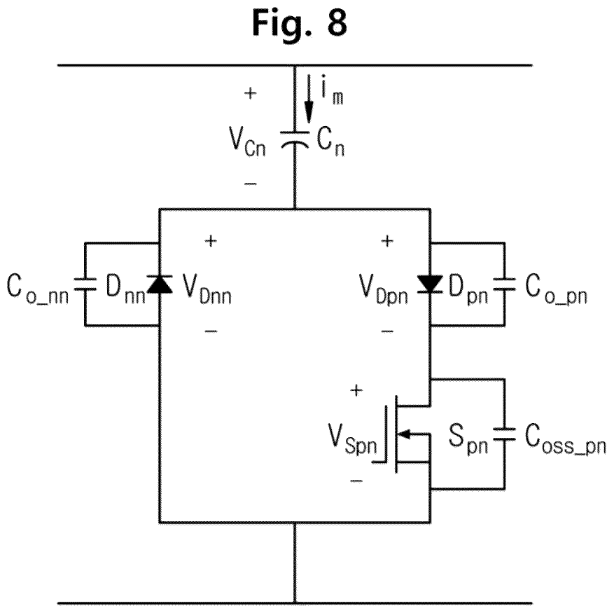

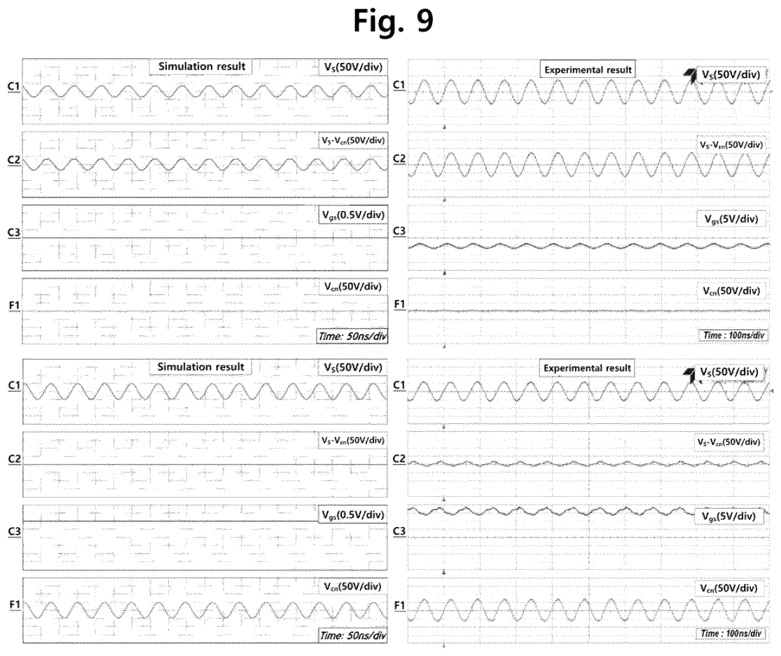

FIGS. 5 to 8 are diagrams for describing a conventional electrical variable capacitor circuit. FIG. 5 is a diagram illustrating an optocoupler variable capacitor circuit, FIG. 6 is a diagram illustrating a half-bridge variable capacitor circuit, FIG. 7 is a diagram illustrating a bidirectional variable capacitor circuit, and FIG. 8 is a diagram illustrating a unidirectional variable capacitor circuit.

Referring to FIGS. 3 to 8, the conventional electrical variable capacitor circuits are compared with the first to third type electrical variable capacitor circuits 100a and 101a of the present invention, and the characteristics of each electrical variable capacitor circuit are shown in Table 1.

TABLE 1

| | | Components for | | Voltage stress of | Current stress of | |
|---|---|---|---|---|---|---|
| Classification | Requirements | extension | Volume | switch | switch | Price |
| Optocoupler | External | S: 2ea, D: 1ea | high | Middle | AC: 0 | High |
| | power source | L: 2ea, C: 1ea | | Vest (≥V_{s, peak}) | DC: i_{m, peak} | |
| Half-bridge | External | S: 2ea, D: 1ea | high | Middle | AC: 0 | High |
| | power source | L: 2ea, C: 1ea | | Vest (≥V_{s, peak}) | DC: i_{m, peak} | |
| Bidirection | — | S: 2ea, D: 2ea, C: 1ea | low | High | AC: iₘ/2 | Middle |
| | | | | 1.7 × Vₚₑₐₖ | DC: 0 | |
| Unidirection | — | S: 2ea, D: 2ea, C: 1ea | low | Low | AC: iₘ/2 | Middle |
| | | | | 0.9 × Vₚₑₐₖ | DC: 0 | |
| First | — | S: 1ea, D: 1ea | middle | Low | AC: iₘ | Low |
| type/second | | L: 1ea, C: 1ea | | 0.5 × Vₚₑₐₖ | DC: i_{m, peak} | |
| type | | | | | | |
| Third type | — | S: 1ea, D: 1ea | middle | Low | AC: 0 | Low |
| | | L: 1ea, C: 1ea | | 0.5 × Vₚₑₐₖ | DC: i_{m, peak} | |

The optocoupler electrical variable capacitor circuit may include a fixed capacitor C₁, a bias power supply V_{bias}, a constant voltage source V_{cc}, a first switch Q₁, a second switch Q₂, a choke inductor L_{choke} having one side connected between the first switch Q₁ and the second switch Q₂, a DC inductor L_{DC} connected to the choke inductor L_{choke} in parallel, a variable capacitor Cᵥₐᵣ connected to the DC inductor L_{DC} in parallel, and a PIN diode D_{PIN} disposed between the other side of the choke inductor L_{choke} and the DC inductor L_{DC}. The half-bridge electrical variable capacitor circuit may include a fixed capacitor C₁, a bias power supply V_{bias}, a first switch Q₁, a second switch Q₂, a choke inductor L_{choke} having one side connected between the first switch Q₁ and the second switch Q₂, a DC inductor L_{DC} connected to the choke inductor L_{choke} in parallel, a variable capacitor Cᵥₐᵣ connected to the DC inductor L_{DC} in parallel, a PIN diode D_{PIN} disposed between the other side of the choke inductor L_{choke} and the DC inductor L_{DC}, and a block capacitor C_{block} connected to the PIN diode D_{PIN} in series and connected to the fixed capacitor C₁ in parallel.

The bidirectional electrical variable capacitor circuit may include a fixed capacitor Cₙ, a first direction diode Dₙₙ, a second direction diode Dₚₙ connected to the first direction diode Dₙₙ in parallel, a first switch Sₙₙ connected to the first direction diode Dₙₙ in series, a second switch Sₚₙ connected to the second direction diode Dₚₙ in series, a first diode capacitor D_{o_nn} connected to the first direction diode Dₙₙ in parallel, a second diode capacitor D_{o_pn} connected to the second direction diode Dₚₙ in parallel, a first switch capacitor C_{oss_nn} connected to the first switch Sₙₙ in parallel, and a second switch capacitor C_{oss_pn} connected to the second switch Sₚₙ in parallel.

The unidirectional electrical variable capacitor circuit may include a fixed capacitor Cₙ, a first direction diode Dₙₙ, a second direction diode Dₚₙ connected to the first direction diode Dₙₙ in parallel, a second switch Sₚₙ connected to the second direction diode Dₚₙ in series, a first diode capacitor Do nn connected to the first direction diode Dₙₙ in parallel, a second diode capacitor D_{o_pn} connected to the second direction diode Dₚₙ in parallel, and a second switch capacitor C_{oss_pn} connected to the second switch Sₚₙ in parallel.

Meanwhile, it can be seen that the first to third type electrical variable capacitor circuits 100a and 101a of the present invention do not use a separate power terminal, thereby having the relatively smallest volume.

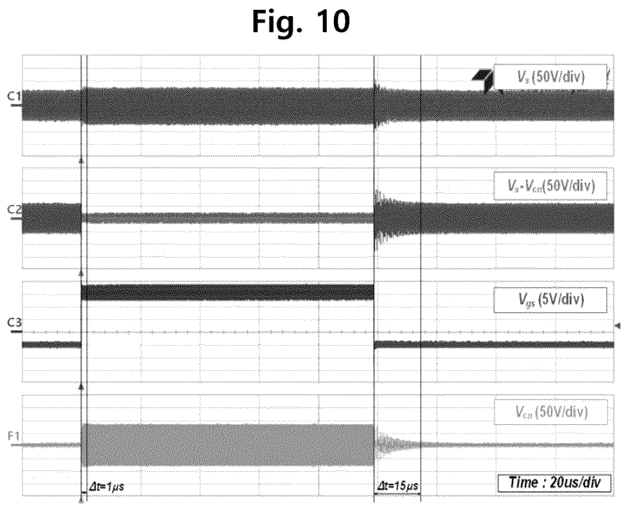

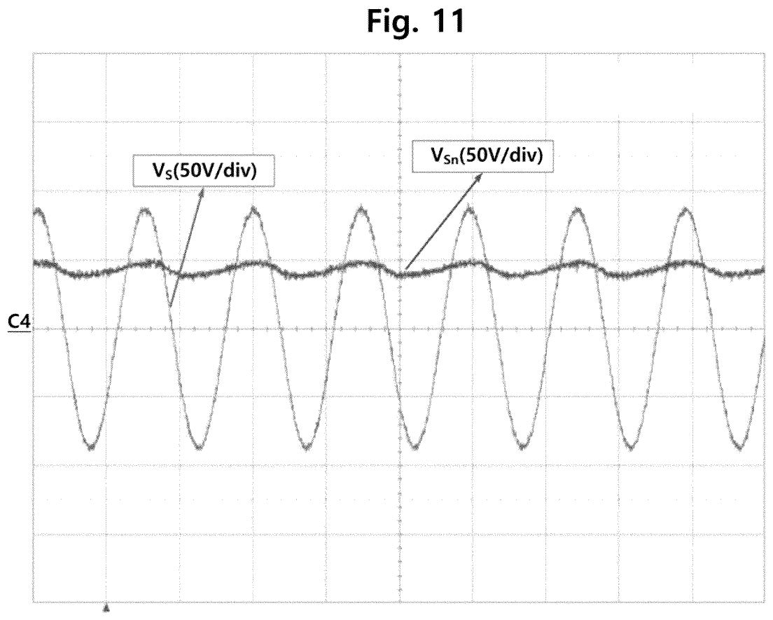

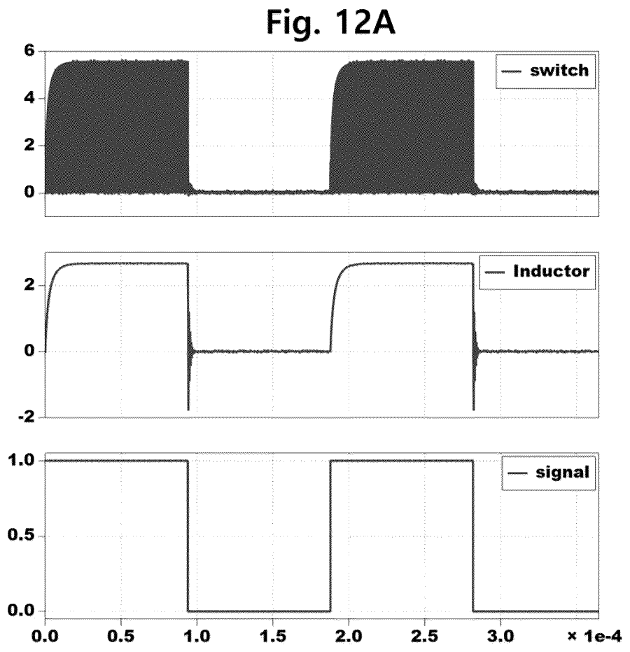

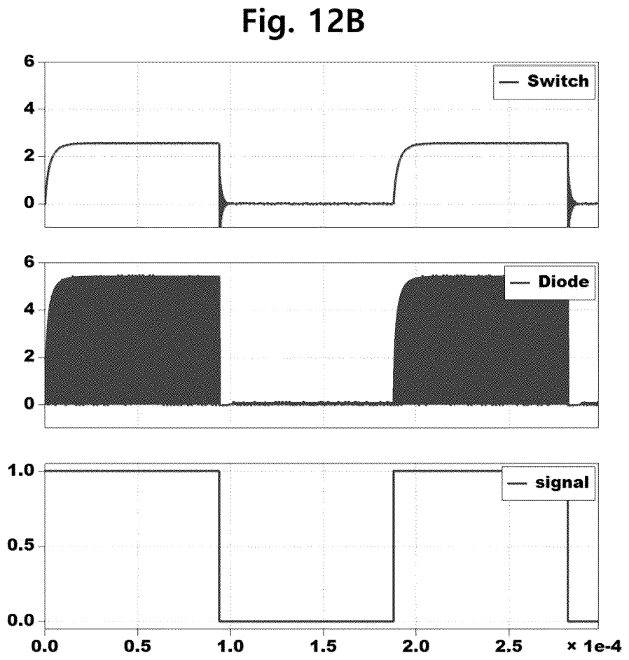

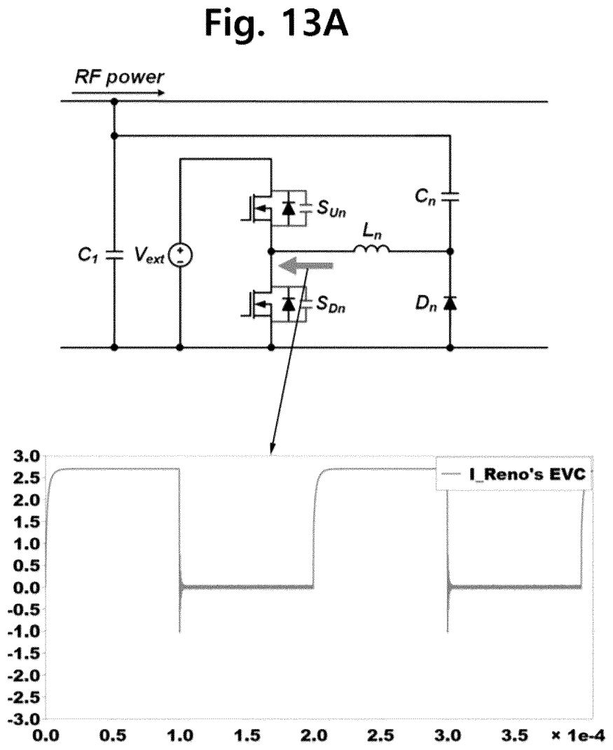

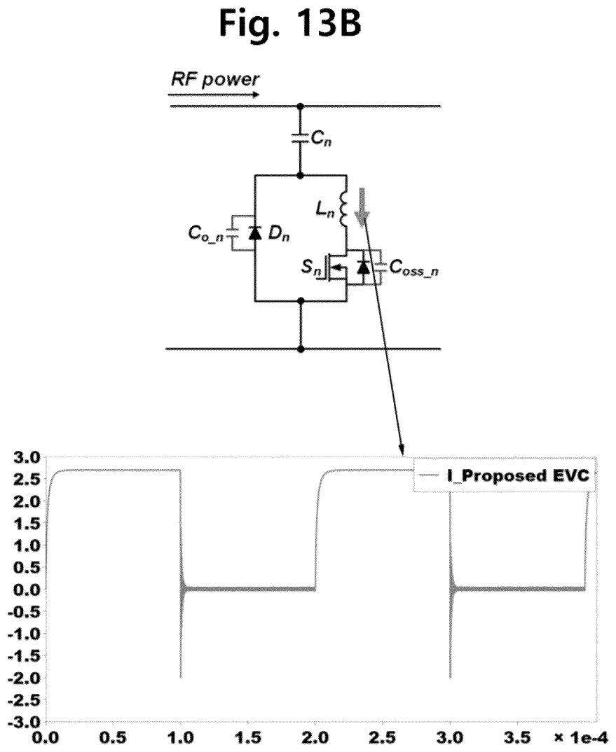

FIG. 10 is a diagram for describing simulation waveforms and experimental waveforms of the first to third type electrical variable capacitor circuits according to the embodiment of the present invention, FIG. 11 is a diagram for describing the capacitance variation times of the first to third type of electrical variable capacitor circuits according to the embodiment of the present invention, and FIG. 12 is a diagram for describing the voltage stress at switches in the first and second type electrical variable capacitor circuits according to the embodiment of the present invention. FIG. 13A is a diagram illustrating a current variation for each component of the first and second type electrical variable capacitor circuits according to the embodiment of the present invention, and FIG. 13B is a diagram illustrating a current variation for each component of the third type electrical variable capacitor circuit according to the embodiment of the present invention. FIG. 14A is a diagram illustrating an inductor current variation in the conventional variable capacitor circuit, and FIG. 14B is a diagram illustrating an inductor current variation in the third type electrical variable capacitor circuit according to the embodiment of the present invention.

Referring to FIGS. 10 to 12, it can be confirmed that waveforms of a simulation (ideal waveforms) and waveforms obtained through actual experiments are similar in the first to third type electrical variable capacitor circuits 100a and 101a. In particular, it can be confirmed that, in the first to third types of electrical variable capacitor circuits 100a and 101a, impedance matching time decreases as capacitance variation time becomes shorter, and the voltage stress at the switches is low.

In addition, referring to FIGS. 13A and 13B, compared to the current flowing in the switch of each of the first and second type electrical variable capacitor circuits 100a, since the current flowing in the switch of the third type electrical variable capacitor circuit 101a is about half, the switch of the third type electrical variable capacitor circuit 101a may be driven with relatively low voltage and current to support stable switch operation. In addition, in the third type electrical variable capacitor circuit 101a, separate RF power does not flow in the switch so that damage to the switch or malfunction of the switch due to RF power can be suppressed.

Meanwhile, as shown in FIGS. 14A and 14B, it can be seen that the conventional capacitor circuit and the third type electrical variable capacitor circuit 101a may perform the same operation. Simulation results under the same conditions show that the RF power does not flow in the switch of the third type electrical variable capacitor circuit 101a of the present invention. In particular, the third type electrical variable capacitor circuit 101a of the present invention has a small volume by applying a relatively small number of elements compared to the conventional capacitor circuit and does not require an external power source, resulting in more improved space efficiency and efficiency power.

Although exemplary embodiments have been described and illustrated to exemplify the technical idea of the present invention, the present invention is not limited to only the configuration and operation as shown and described, and those skilled in the art will appreciate that many changes and modifications are possible to the present invention without departing from the scope of the technical idea. Accordingly, all such appropriate changes, modifications and equivalents shall be considered to fall within the scope of the present invention.

1. A semiconductor processing system comprising:
a radio frequency (RF) power supply configured to generate and supply RF power;
a plasma chamber configured to receive the RF power from the RF power supply; and
an impedance matching circuit disposed between the RF power supply and the plasma chamber and configured to match output impedance to the plasma chamber,
wherein the impedance matching circuit includes a plurality of electrical variable capacitor circuits, and
at least one electrical variable capacitor circuit among the plurality of electrical variable capacitor circuits includes:
a first node connected to one side of the RF power supply;
a second node connected to the other side of the RF power supply;
a variable capacitor connected to the first node;
an inductor connected to the variable capacitor in parallel;
a switch connected to the inductor in series; and
a PIN diode connected to the inductor and the switch in parallel.

2. The semiconductor processing system of claim 1, wherein the plurality of electrical variable capacitor circuits have the same structure.

3. The semiconductor processing system of claim 1, wherein the plurality of electrical variable capacitor circuits include 8 to 28 electrical variable capacitor circuits.

4. The semiconductor processing system of claim 1, wherein a cathode of the PIN diode is connected to the variable capacitor, and an anode of the PIN diode is connected to the second node.

5. An electrical variable capacitor circuit comprising:
a first node connected to one side of a radio frequency (RF) power supply;
a second node connected to the other side of the RF power supply;
a variable capacitor having one side connected to the first node;
a PIN diode having one side and an inductor having one side connected to the other side of the variable capacitor in parallel, and
a switch connected to the other side of the inductor in series and connected to the PIN diode in parallel.

6. The electrical variable capacitor circuit of claim 5, wherein:
a cathode terminal of the PIN diode is connected to the other side of the variable capacitor; and
an anode terminal of the PIN diode is connected to the second node.
